(19) United States
(12) Patent Application Publication
(10) Pub. No.: US 2005/0067666 A1
(43) Pub. Date: Mar. 31, 2005

(54) Device for electrical connection between two wafers and fabrication process of a microelectronic component comprising such a device

(75) Inventor: Philippe Robert, Grenoble (FR)

Correspondence Address: OLIFF & BERRIDGE, PLC, P.O. BOX 19928, ALEXANDRIA, VA, 22320, US

(73) Assignee: COMMISSARIAT A L'ENERGIE ATOMIQUE, Paris (FR)

(21) Appl. No.: 10/909,423

(22) Filed: Aug. 3, 2004

(30) Foreign Application Priority Data
Aug. 21, 2003 (FR) 03 10070

(51) Int. Cl. H01L 21/00; H01L 29/84

(52) U.S. Cl. 257/415; 438/50; 257/417; 257/619

(57) ABSTRACT

A device for electrical connection between first and second wafers comprises at least first and second contact elements respectively integral to opposite faces of the first and second wafers. The first contact element comprises a salient zone whereas the second contact element is formed by a beam suspended above a cavity formed in the second wafer. The salient zone has a smaller width than the width of the cavity and it can form a stud or a rib. Once the first and second wafers have been assembled, the salient zone and beam come into contact above the cavity and the pressure exerted by the salient zone generates a deformation of the beam, making it flexible.

### BACKGROUND OF THE INVENTION

The invention relates to a device for electrical connection between first and second wafers used the microtechnologies field, said device comprising at least first and second contact elements respectively integral to the opposite faces of the first and second wafers and respectively achieved in the form of at least one thin layer, the first contact element comprising a salient zone.

The invention also relates to a fabrication process of a microelectronic component comprising such an electrical connection device.

### STATE OF THE ART

To assemble two wafers such as those used in the microtechnology field while ensuring electrical conduction between the two wafers, it is common practice to arrange contact studs between the two wafers. Contact studs are in fact known to guarantee maximum reliability and good contact resistance.

Contact studs can for example be arranged respectively on the opposite faces of the two wafers so that, once the two wafers have been assembled, the studs of each wafer come into contact with the corresponding studs of the other wafer. However, the faces of the wafers on which the contact studs are arranged are not necessarily flat, which may prevent contact between two corresponding studs. The flatness defects of one or both of the wafers may be due, for example, to the presence of non-homogeneities at the surface of the wafers or to the presence of sealing stops or steps. For example, the surface of one of the wafers may have a certain roughness or the surfaces of both wafers may be non-complementary. Furthermore, such rigid studs do not allow any deformation between the assembled wafers. Indeed, once the wafers have been assembled, they can undergo different thermal expansions which generate a movement of each wafer with respect to the other wafer in opposite directions, rigid studs not allowing such a movement.

It is therefore preferable to make flexible electrical connections between the two wafers so as not to oppose the movements due to a thermal expansion and to compensate flatness defects. Thus, in the document “Sea of Leads Ultra High-Density Compliant Wafer-Level Packaging Technology” (2002 Electronic Component and Technology Conference), Muhannad S. Bakir et al. propose to make flexible contacts by means of a polymer membrane. The polymer membrane forms a bridge on the surface of a wafer and it is partially covered by a thin layer of gold one end whereof is fixedly secured to the wafer and the other end whereof comprises a solder ball designed to achieve the contact with another wafer. Use of these flexible contacts does however remain limited. Indeed, the use of a flexible membrane made of polymer material limits the use of the contacts thus achieved at temperatures above 200° C. Moreover, this type of contacts does not enable sealing of the two wafers up to mechanical contact to be achieved, which does not enable a hermetic and/or tight sealing to be achieved. Finally such contacts are generally not easy to achieve, the fabrication process being fastidious and costly.

### OBJECT OF THE INVENTION

One object of the invention is to achieve a device for electrical connection between two wafers, enabling the irregularities of the surfaces of one or both of the wafers to be compensated, resistant to temperatures of more than 20° C. and possibly enabling sealing of the two wafers to be performed, while being easy to implement and preferably making use of techniques such as those used in the microelectronics field.

According to the invention, this object is achieved by the fact that the second contact element is formed by a beam suspended above a cavity formed in the second wafer, the salient zone having a smaller width than the width of the cavity.

According to one development of the invention, the first wafer comprises a protrusion whereon a metallic layer is deposited so as to form said salient zone.

According to a preferred embodiment, the beam is formed by a thin dielectric layer covered by a thin metallic layer.

According to another embodiment, the beam is formed by a thin metallic layer.

Another object of the invention is to achieve a fabrication process of a microelectronic component comprising such an electrical connection device that is reliable, inexpensive, simple and preferably able to be performed by means of the technologies used in the microelectronics field.

According to the invention, this object is achieved by the fact that the process consists in assembling the first and second wafer establishing an electrical connection between the salient zone of the first contact element and the beam of the second contact element, above the cavity.

According to one development of the invention, the process consists in applying an insulating layer between the first and second assembled wafers so as to seal them.

### BRIEF DESCRIPTION OF THE DRAWINGS

Other advantages and features will become more clearly apparent from the following description of particular embodiments of the invention given as non-restrictive examples only and represented in the accompanying drawings, in which:

FIG. 1 is a cross-sectional view of a connection device according to the invention, in exploded form.

FIG. 2 represents, in cross-section, a microelectronic component comprising a connection device according to the invention, with a salient zone having a smaller thickness than the thickness of the cavity.

FIG. 3 represents, in cross-section, a microelectronic component comprising a connection device according to the invention, with a salient zone having a greater thickness than the thickness of the cavity.

FIG. 4 represents, in perspective and in exploded form, a particular embodiment of a microelectronic component comprising a connection device according to the invention.

FIGS. 5 to 8 represent, in cross-section, different steps of formation of a first part of the connection device according to FIG. 1.

FIGS. 9 to 11 represent, in cross-section, different steps of formation of a second part of the connection device according to FIG. 1.

### DESCRIPTION OF PARTICULAR EMBODIMENTS

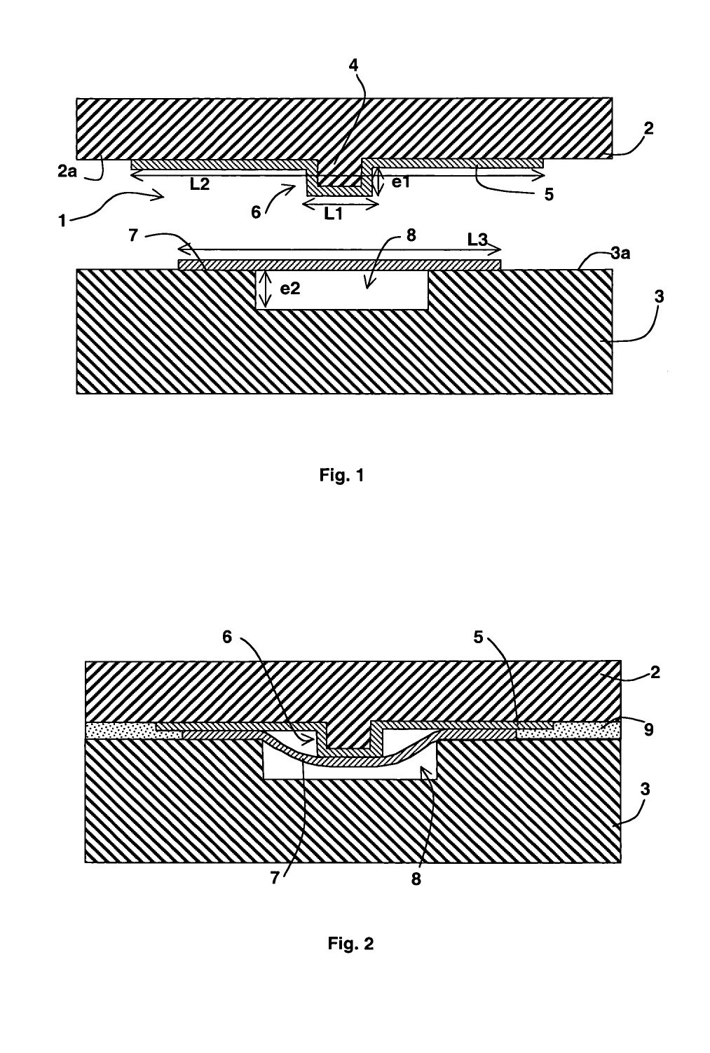

As represented in FIG. 1, in a microelectronic component comprising first and second wafers 2 and 3, an electrical connection device 1 comprises at least first and second contact elements respectively integral to the opposite faces 2a et 3a of the first and second wafers 2 and 3. The first and second contact elements are designed to be placed in contact with one another to achieve an electrical connection when the first and second wafers are assembled. Each wafer 2 or 3 can for example be made of silicon or glass. Thus, the first wafer can for example form a substrate whereon an integrated circuit is arranged whereas the second wafer can be a substrate whereon there is arranged a Micro Electro Mechanical System (MEMS).

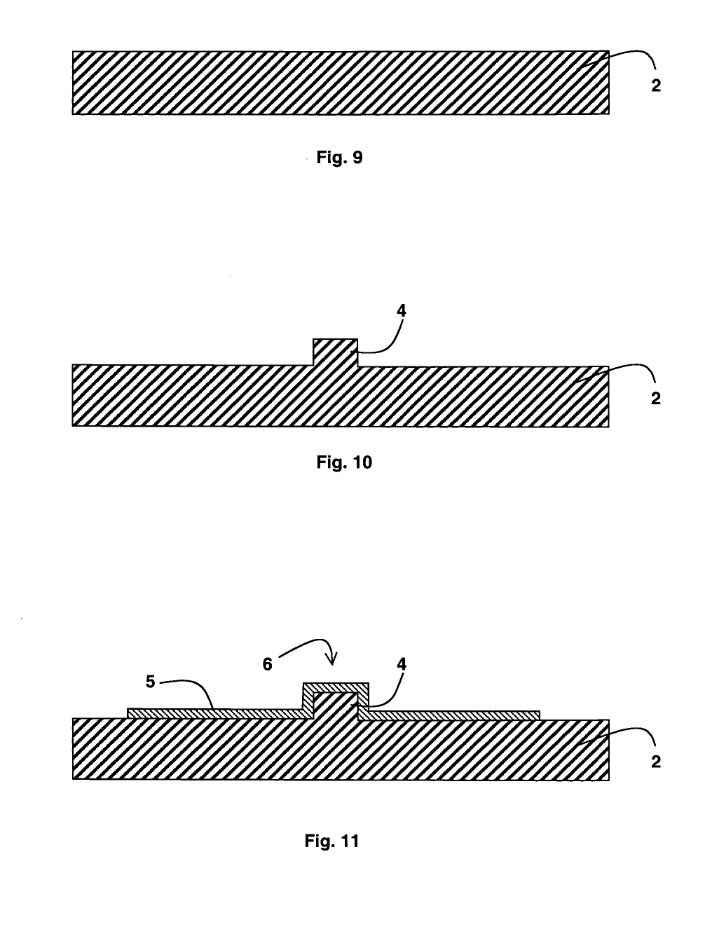

Thus, in FIG. 1, the face 2a of the first wafer 2 comprises a protrusion 4 and a metallic layer 5 is arranged on the face 2a, so as to cover the protrusion 4 and to form a salient zone 6. The metallic layer 5 preferably has a greater width L2 than the width L1 of the protrusion 4 so that the parts of the face 2a, adjacent to the protrusion 4, are covered by the ends of the metallic layer 5. The protrusion 4 and metallic layer 5 therefore form the first contact element of the connection device. The salient zone 6 can be in the form of a stud or rib. Thus, for example purposes and as represented in FIGS. 9 to 11, the first contact element can be achieved by etching the protrusion 4 on the face 2a of the first wafer 2 and then by depositing the metallic layer 5, which can for example be gold or aluminium, on the face 2a. The shape of the first contact element is then determined by an etching step.

The second contact element of the second wafer 3 is formed by a beam 7 suspended above a cavity 8 formed in the second wafer 3, the width L1 of the salient zone 6 being smaller than the width L2 of the cavity 8. Both of the ends of the beam 7 are resting on each side of the cavity 8, on the face 3a of the second wafer 3. The beam 7 is preferably formed by a thin metallic layer, for example of gold or aluminium, or by a thin dielectric layer covered by a thin metallic layer.

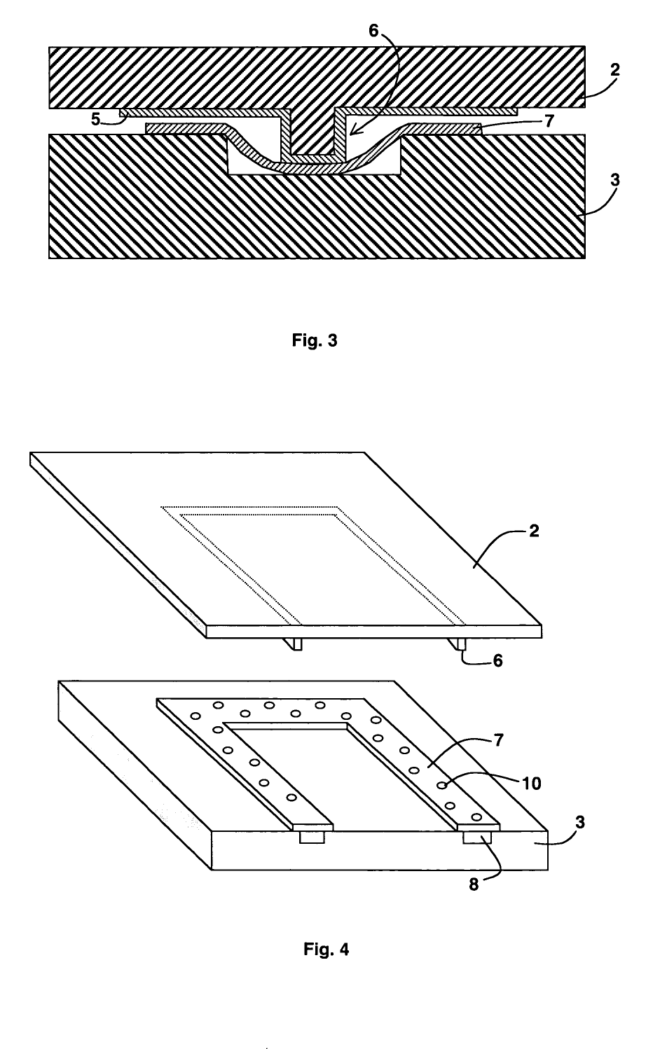

Thus, as represented in FIGS. 2 and 3, such a connection device enables a microelectronic component to be achieved by assembling the two wafers 2 and 3 and establishing an electrical contact between the salient zone 6 and the beam 7, above the cavity 8. The thickness of the beam 7 being sufficiently small, it can be deformed under the pressure applied by the salient zone 6, above the cavity 8. This enables a flexible electrical connection to be formed that is able to compensate any flatness defects of the wafers and allows thermal expansion of the wafers when deforming. The pressure exerted between the salient zone and the beam can in fact be adjusted according to the thickness and shape of the beam 7 and according to the width of the salient zone 6. Thus, a relatively thick beam 7 having a fairly small width L3 has a sufficiently large stiffness to create a strong pressure between the salient zone and the beam. Likewise, a salient zone 6 having a small width L1 enables a strong pressure to be exerted on the beam 7 which favors a contact with a good electrical resistance. Moreover, the small dimensions of the salient zone 6 enable a high contact density to be obtained.

When the thickness e1 of the salient zone 6 is smaller than the thickness e2 of the cavity 8, such a connection device enables sealing of the two wafers to be performed. For example, the thickness e2 of the cavity 8 can for example be 5 nanometers whereas the thickness e1 of the salient zone 6 can be 3 nanometers. Thus, as illustrated in FIG. 2, once the wafers 2 and 3 have been assembled, contact is established not only between the salient zone 6 and the part of the beam 7 suspended above the cavity 8 but also between the ends of the metallic layer 5 and of the beam 7. Contact between the ends of the metallic layer and of the beam 7 therefore enables the cavity 8 to be tightly sealed. An insulating layer 9, for example made of polymer or oxide, can also be applied between the two assembled wafers so as to seal the wafers. This type of connection thus enables encapsulated microelectronic components such as resonant microsensors to be achieved in a vacuum, while preserving the quality of the vacuum. In another embodiment, represented in FIG. 3, the thickness e1 of the salient zone 6 is greater than the thickness e2 of the cavity 8 so that once the two wafers have been assembled, only the salient zone 6 is in contact with the beam 7. The beam 7 is then deformed under the pressure exerted by the salient zone until it comes into contact with the bottom of the cavity 8. Once the first and second wafers have been assembled, the assembly forms a microelectronic component.

Such a connection device not only enables a flexible electrical contact to be formed between two wafers, but it also enables the first and second contact elements to have any type of appropriate shape. Thus, as illustrated in FIG. 4, the salient zone 6 of the first contact element can be in the form of a rib of annular shape. The beam 7 and cavity 8 also have an annular shape, so that the salient zone 6 is in contact with the beam 7 over the whole length of the salient zone 6. The beam 7 and salient zone 6 can have lengths comprised between a few tens of micrometers and a few hundreds of micrometers, which greatly increases the contact density. In FIG. 4, holes are arranged in the beam 7 so as to suspend the beam 7 above the cavity 8 when fabrication of the second connection element is performed.

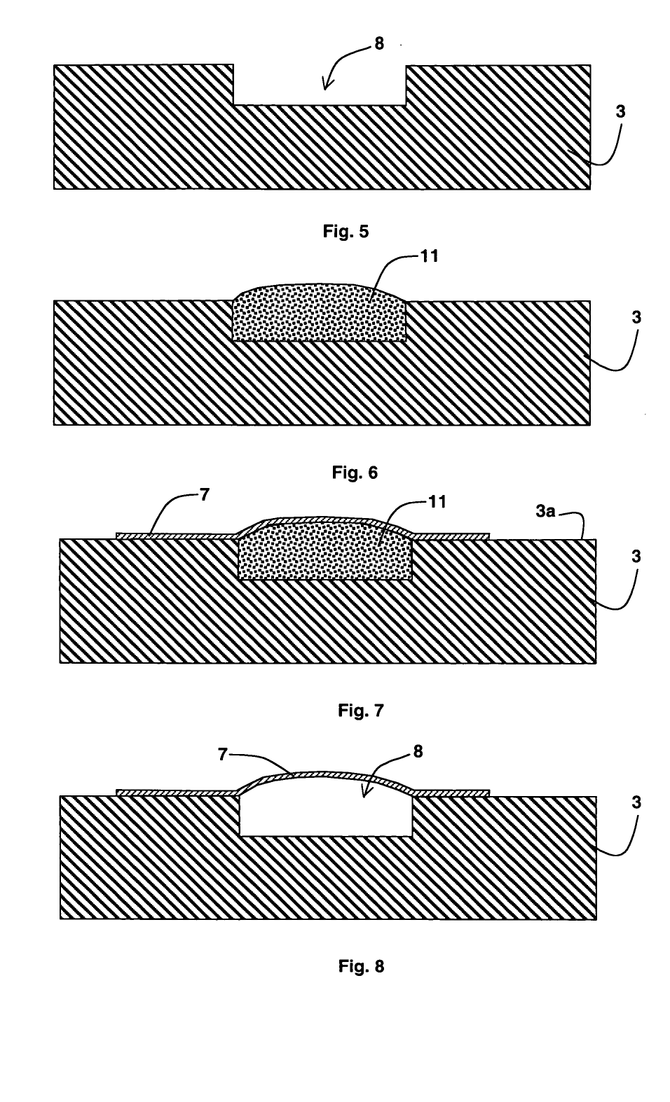

Thus, in a particular embodiment represented in FIGS. 5 to 8, formation of the second connection element consists in etching the second wafer 3 to form the cavity 8 (FIG. 5). A sacrificial layer 11, for example made of polymer, is then deposited, lithographied and etched in the cavity 8 (FIG. 6) so as to enable deposition of the beam 7 in the form of a thin metallic layer. The beam 7 is therefore then deposited on the sacrificial layer 11 and on the adjacent parts of the face 3a of the wafer 3 (FIG. 7). Then the shape of the beam 7 is defined by a lithography and etching step and the holes 10 are formed in the beam 7 so as to have access to the sacrificial layer 11 to perform dry etching enabling the sacrificial layer 11 to be eliminated (FIG. 8). The beam 7 is then suspended above the cavity 8.

Such a connection device presents the advantage of achieving a thermally stable, flexible electrical contact between the first and second wafers, enabling microelectronic components able to operate at temperatures greater than or equal to 200° C. to be fabricated. Finally, such microelectronic components are easy to achieve, the fabrication process being able to be collective, relatively inexpensive and compatible with the techniques used in the microelectronics field.

The invention is not limited to the embodiments described above. Thus, the connection device can comprise a plurality of first and second contact elements. Furthermore, the connection device can enable two individual components to be electrically connected to one another or components present on a wafer to be electrically connected with another component. It also enables integrated circuits and/or microsystems to be connected to one another, in collective manner, when they are arranged on substrates. The connection device applies in particular to any device comprising a stack of electronic components, such as a “MEMS” type microsystem surmounted on an electronic circuit, in order to ensure an electrical contact between the different components of the device.

1. Device for electrical connection between first and second wafers used in the microtechnologies field, said device comprising at least first and second contact elements respectively integral to the opposite faces of the first and second wafers and respectively achieved in the form of at least one thin layer, the first contact element comprising a salient zone, device wherein the second contact element is formed by a beam suspended above a cavity formed in the second wafer, the salient zone having a smaller width than the width of the cavity.

2. Device according to claim 1, wherein the first wafer comprises a protrusion whereon a metallic layer is deposited so as to form said salient zone.

3. Device according to claim 1, wherein the salient zone forms a stud.

4. Device according to claim 1, wherein the salient zone forms a rib.

5. Device according to claim 1, wherein the beam is formed by a thin dielectric layer covered by a thin metallic layer.

6. Device according to claim 1, wherein the beam is formed by a thin metallic layer.

7. Device according to claim 1, wherein the beam has a length comprised between a few tens of micrometers and a few hundreds of micrometers.

8. Device according to claim 1, wherein the thickness of the salient zone is smaller than or equal to the thickness of the cavity.

9. Device according to claim 1, wherein the thickness of the salient zone is greater than the thickness of the cavity.

10. Fabrication process of a microelectronic component comprising an electrical connection device according to claim 1, consisting in assembling the first and second wafers establishing an electrical connection between the salient zone of the first contact element and the beam of the second contact element, above the cavity.

11. Process according to claim 10, consisting in applying an insulating layer between the first and second assembled wafers so as to seal them.
